(19) United States
(12) Patent Application Publication
(10) Pub. No.: US 2026/0226991 A1
(43) Pub. Date: Aug. 6, 2026

(54) COMPONENT AND ASSEMBLY

(71) Applicants: NITTO DENKO CORPORATION, Ibaraki-shi, Osaka (JP); FUJIKURA COMPOSITES Inc., Tokyo (JP)

(72) Inventors: Kou UEMURA, Osaka (JP); Hiroyuki FUJITA, Osaka (JP); Kouji TSUCHIYA, Saitama (JP); Kenji IZAWA, Saitama (JP)

(21) Appl. No.: 19/153,159

(22) PCT Filed: Feb. 2, 2024
(86) PCT No.: PCT/JP2024/003576

§ 371 Date: Aug. 1, 2025

(30) Foreign Application Priority Data
Feb. 3, 2023 (JP) 2023-015340

(51) Int. Cl. F16K 7/12

(52) U.S. Cl. CPC F16K 7/12

(57) ABSTRACT

A component 1a includes an attachment member 10 and a covering member 20. The attachment member 10 is independently fixed to a housing 2 so as to cover an opening 2a of the housing 2. The covering member 20 covers the attachment member 10.

### TECHNICAL FIELD

The present invention relates to a component and an assembly.

### BACKGROUND ART

In conventionally known components, a component is attached to a housing so as to cover an opening of the housing.

For example, Patent Literature 1 describes a pressure compensation device for a housing. This pressure compensation device has a lattice-shaped cage. The cage is formed of an inner half and an outer half. Inside the cage, a gas-permeable diaphragm and an umbrella-shaped valve are arranged between the inner half and the outer half. The pressure difference between the inner side and the outer side of the pressure compensation device acts on the diaphragm and the umbrella-shaped valve. When this pressure difference exceeds a threshold limit, the umbrella-shaped valve opens a direct path between the inner and outer sides to allow emergency gas venting from the inner side. This pressure compensation device is understood to be attached to the housing via an O-ring.

Patent Literature 2 describes an assembly, which is configured to allow gases to pass between a casing and an environment through a vent under normal pressure conditions. The assembly is configured to allow gases to escape the casing by bypassing the vent upon a high-pressure event inside the casing. The assembly has a vent housing, a coupling structure, a mounting surface, a vent, and a relief valve. The coupling structure is configured to couple the assembly to the casing about an opening defined by the casing. A seal of an elastomer material is used for sealing between the assembly and the casing. The seal abuts the coupling structure.

Patent Literature 3 describes a pressure relief valve for a battery pack that is attached to an opening portion formed in a battery pack case. This battery pack pressure relief valve includes a case and a cover, wherein the case has a discharge hole communicating with the opening portion and a valve mechanism capable of opening and closing the discharge hole. The cover forms a passage for discharging gas discharged from the discharge hole between the case and the cover when the cover is attached to the case. The valve mechanism includes a valve member capable of blocking the discharge hole and a biasing member that biases the valve member to a closed position for closing the discharge hole. The biasing member is, for example, a double torsion spring. The case has a connecting portion inserted into the opening portion of the battery pack case, and the outer peripheral surface of this connecting portion is provided with a first sealing member and a second sealing member. The first sealing member is interposed between the inner peripheral surface of the opening portion of the pack case and the case. The second sealing member abuts the surface of the pack case when the pressure relief valve is attached to the pack case.

Patent Literature 4 describes a ventilation unit, which includes a first ventilation body and a second ventilation body. The first ventilation body permits gas to flow from an inside of a housing to an outside of the housing when internal pressure, which is pressure inside the housing, is higher than external pressure, which is pressure outside the housing, by a value not less than a predetermined value, and is capable of returning to block flow of the gas from the inside of the housing to the outside of the housing. The second ventilation body permits gas to flow between the inside of the housing and the outside of the housing even when a pressure difference between the internal pressure and the external pressure is less than the predetermined value. The ventilation unit includes a holding member to be attached to the housing and a sealing member. The sealing member is disposed between the holding member and the housing to seal between the holding member and the housing.

### CITATION LIST

### Patent Literature

Patent Literature 1: JP 2018-181329, A
Patent Literature 2: JP 2020-515783, A
Patent Literature 3: JP 2020-194719, A
Patent Literature 4: WO 2018/199238

### SUMMARY OF INVENTION

### Technical Problem

The component described in Patent Literatures 1 to 4 is understood to be fixed to a housing by cooperation between a sealing member such as an O-ring and another member in contact with the sealing member. Therefore, a large number of members are required to attach these components to a housing.

Accordingly, the present invention provides a component that can be attached to a housing to cover the opening of the housing with a simple configuration, and is advantageous from the viewpoint of protecting the members fixed to the housing.

### Solution to Problem

The present invention provides a component configured to be attached to a housing so as to cover an opening of the housing, the component including:
an attachment member to be independently fixed to the housing or joined to the housing so as to cover the opening, and
a covering member covering the attachment member.

### Advantageous Effects of Invention

The above-mentioned component can be attached to a housing to cover the opening of the housing with a simple configuration, and the component is advantageous from the viewpoint of protection of the member fixed to the housing.

### BRIEF DESCRIPTION OF DRAWINGS

FIG. 1 is a side view showing an example of an assembly according to the present invention.

FIG. 2 is an exploded perspective view of the assembly shown in FIG. 1.

FIG. 3A is a cross-sectional view of the assembly shown in FIG. 1, taken along a line A-A.

FIG. 3B is a cross-sectional view of the assembly shown in FIG. 1, taken along a plane B.

FIG. 4 is a cross-sectional view of a component in a state not attached to a housing.

FIG. 5 is a perspective view showing a peripheral portion of a covering member.

FIG. 6 is a cross-sectional view of an assembly when external pressure is applied.

FIG. 7 is a cross-sectional view showing another example of component.

FIG. 8 is a plan view showing another example of covering member.

FIG. 9 is a cross-sectional view showing another example of assembly according to the present invention.

FIG. 10 is a cross-sectional view showing yet another example of assembly according to the present invention.

FIG. 11 is a cross-sectional view showing yet another example of assembly according to the present invention.

### DESCRIPTION OF EMBODIMENTS

Hereinafter, embodiments of the present invention will be described with reference to the drawings. Note that the present invention is not limited to the following embodiments.

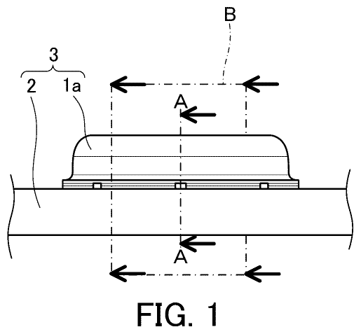

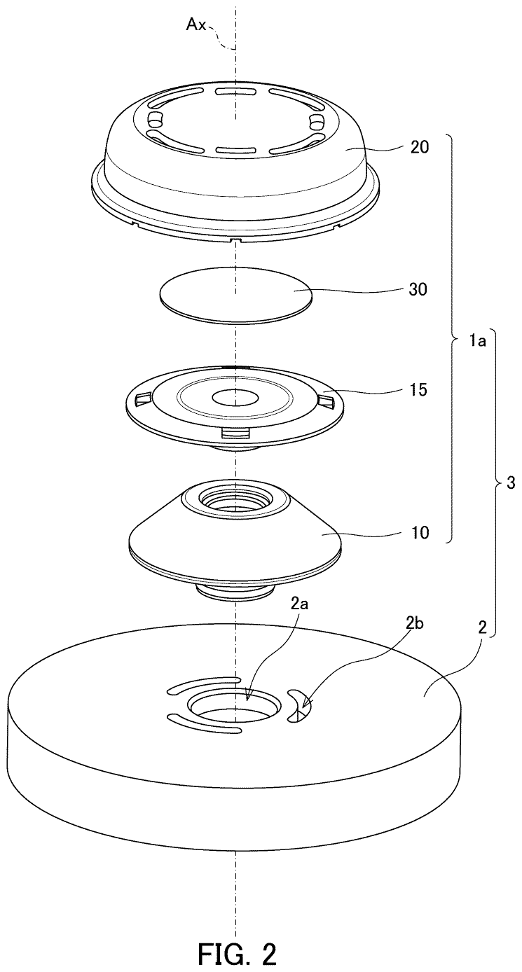

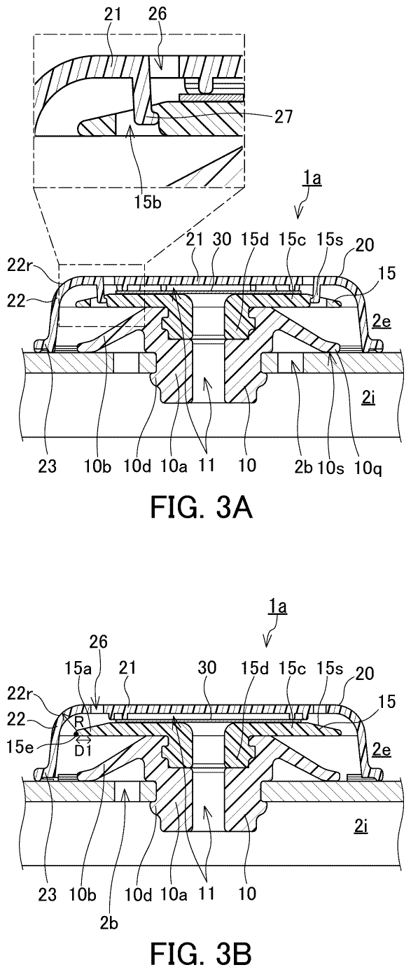

As shown in FIG. 1, FIG. 2, FIG. 3A, and FIG. 3B, a component 1a is attached to a housing 2 so as to cover an opening 2a of the housing 2. The component 1a includes an attachment member 10 and a covering member 20. The attachment member 10 is independently fixed to the housing 2 so as to cover the opening 2a of the housing 2. In other words, the attachment member 10 can be fixed to the housing 2 without requiring cooperation with other members such as an O-ring. The covering member 20 covers the attachment member 10.

Since the attachment member 10 is independently fixed to the housing 2 so as to cover the opening 2a of the housing 2, the component 1a can be attached to the housing 2 with a simple configuration without using a sealing member such as an O-ring. In addition, since the attachment member 10 is covered with the covering member 20, the attachment member 10 is easily protected from external loads such as a water flow.

The method of independently fixing the attachment member 10 to the housing 2 is not limited to a specific method. For example, it may be a press-fitting method. The attachment member 10 includes, for example, a part to be inserted into the opening 2a, and the diameter of the part is slightly larger than the diameter of the opening 2a. When the attachment member 10 is inserted into the opening 2a while being pressurized, the part inserted into the opening 2a deforms to be in airtight contact with the housing 2 in the interior of the opening 2a. As a result, the attachment member 10 is independently fixed to the housing 2.

The material forming the attachment member 10 is not limited to a specific material. The material forming the attachment member 10 may be, for example, an elastomer (elastic resin). The elastomer may be rubber. The elastomer may be, for example, nitrile rubber (NBR), ethylene-propylene rubber (EPDM), silicone rubber, fluorine rubber, acrylic rubber, hydrogenated rubber, or various thermoplastic elastomers.

The housing 2 is formed, for example, from a material that exhibits higher rigidity against compressive deformation than the attachment member 10. The material for forming the housing 2 may be metal or resin.

As shown in FIG. 2, the component 1a has, for example, a structure that is rotationally symmetrical about an axis Ax. For example, when the component 1a is viewed along the axis Ax, the covering member 20 covers the entire attachment member 10. Therefore, the attachment member 10 is more easily protected from external loads such as a water flow.

The covering member 20 may be shaped without any particular limitations as long as the covering member 20 is capable of covering the attachment member 10. As shown in FIG. 3A, the covering member 20 includes, for example, a flat portion 21 and a side portion 22. The flat portion 21 forms the central portion of the covering member 20. The side portion 22 extends from flat portion 21 and forms a peripheral edge of the covering member 20. With this configuration, the attachment member 10 is easily protected from external loads imposed from various directions.

The material of the covering member 20 is not limited to a specific material. The material forming the covering member 20 is, for example, resin.

As shown in FIG. 3B, in the covering member 20, the side portion 22 has a curved portion 22r. The curved portion 22r adjoins to the flat portion 21. In the case where an attachment member is independently fixed to a housing, it may be difficult to insert the attachment member into an opening of the housing in comparison with a case where the attachment member is fixed in cooperation with a sealing member such as an O-ring. On the other hand, with this configuration, for example, even if the covering member 20 and the outer surface of the housing 2 are in contact with each other at the time of inserting the attachment member 10 into the opening 2a of the housing 2 to attach the component 1a to the housing 2, the covering member 20 can deform appropriately, making it easy to insert the attachment member 10 into the opening 2a. Therefore, the component 1a can be easily attached to the housing 2.

The curvature radius R of a contour formed with the outer surface of the covering member 20 in the cross-section of the curved portion 22r along the thickness direction of the flat portion 21 is not limited to a specific value. The curvature radius R is, for example, 1.0 mm or more. In this case, the component 1a can be easily attached to the housing 2. The curvature radius R may be 1.5 mm or more. The curvature radius R is, for example, 6.0 mm or less.

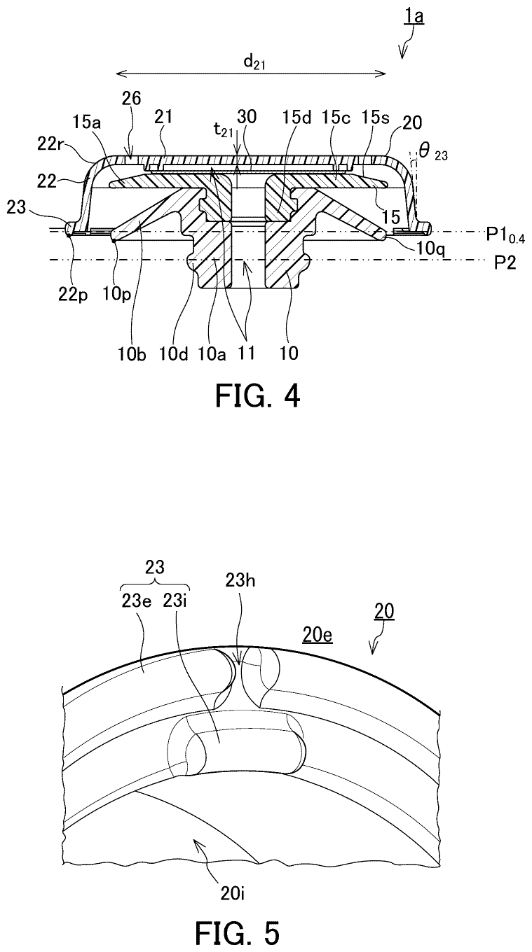

As shown in FIG. 4, an angle 023, which is an angle formed between the outer surface of the side portion 22 and a straight line parallel to the axis Ax and intersecting the side portion 22, is not limited to a specific value. The angle θ₂₃ is, for example, 2° or more. With this configuration, even if the covering member 20 and the outer surface of the housing 2 are in contact with each other at the time of inserting the attachment member 10 into the opening 2a to attach the component 1a to the housing 2, the covering member 20 can easily deform so that the flat portion 21 approaches the outer surface. Therefore, the attachment member 10 can be easily inserted into the opening 2a, and the component 1a can be easily attached to the housing 2. The angle θ₂₃ may be 2.5° or more, or 3° or more.

A thickness t₂₁ of the flat portion 21 is not limited to a specific value. The thickness t₂₁ is, for example, 0.8 mm or more and 2.3 mm or less. Since the thickness t₂₁ is 0.8 mm or more, the covering member 20 is more likely to have a desired strength, and the covering member 20 is less likely to be damaged at the time of inserting the attachment member 10 into the opening 2a and attaching the component 1a to the housing 2. Since the thickness t₂₁ is 2.3 mm or less, even if the covering member 20 is in contact with the outer surface of the housing 2 at the time of inserting the attachment member 10 into the opening 2a and attaching the component 1a to the housing 2, the covering member 20 is likely to deform appropriately, making it easy to insert the attachment member 10 into the opening 2a. The thickness t₂₁ may be 0.9 mm or more, or 1.0 mm or more, and may also be 2.2 mm or less, 2.1 mm or less, or 2.0 mm or less.

The diameter d₂₁ of the flat portion 21 is not limited to a specific value. The diameter d₂₁ is, for example, 25 mm or more. In this case, even if the covering member 20 is in contact with the outer surface of the housing 2 at the time of inserting the attachment member 10 into the opening 2a and attaching the component 1a to the housing 2, the covering member 20 is likely to deform appropriately, making it easy to insert the attachment member 10 into the opening 2a. In particular, when the thickness t₂₁ is 0.8 mm or more and 2.3 mm or less, and the diameter d₂₁ is 25 mm or more, the attachment member 10 may be easily inserted into the opening 2a. The diameter d₂₁ is, for example, 100 mm or less. The diameter d₂₁ may be 30 mm or more, 35 mm or more, 40 mm or more, 45 mm or more, or 50 mm or more, and may be 90 mm or less, 80 mm or less, or 70 mm or less.

As shown in FIG. 3A, FIG. 3B, and FIG. 5, the covering member 20 includes, for example, a peripheral portion 23. As shown in FIG. 5, the peripheral portion 23 includes, for example, an outer wall 23e and an inner wall 23i. The outer wall 23e has a first opening 23h. The first opening 23h is formed between an interior 20i of the covering member 20 and an exterior 20e of the covering member 20. The inner wall 23i covers the first opening 23h along the outer wall 23e in the interior 20i of the covering member 20. With this configuration, even if water flows in the exterior 20e of the covering member 20 toward the first opening 23h, the inner wall 23i may prevent the water from directly striking the attachment member 10. In addition, even if water flows into the interior 20i of the covering member 20, the water is easily drained to the exterior of the covering member 20 through a space enclosed by the inner wall 23i, the outer wall 23e, and a part of the outer wall 23e forming the first opening 23h.

The first opening 23h is formed, for example, as a recess formed at a tip of the side portion 22. This recess is open at both ends in a direction perpendicular to the axis Ax and open at one end in a direction parallel to the axis Ax. The outer wall 23e, for example, has a plurality of first openings 23h. The number of first openings 23h is, for example, 2 or more and 16 or less. The first openings 23h are formed at equal intervals about the axis Ax.

As shown in FIG. 3A and FIG. 3B, the component 1a further includes, for example, a shielding structure 15a. The flat portion 21 of the covering member 20 has, for example, a through hole 26. The shielding structure 15a is disposed between the through hole 26 and the attachment member 10 in the thickness direction of the flat portion 21. With this configuration, for example, even if water flows in the exterior of the covering member 20 toward the through hole 26 and the water enters the interior of the covering member 20, the water flow is deflected by the shielding structure 15a and is less likely to directly strike the attachment member 10.

For example, in the interior of the covering member 20, the through hole 26 is covered with the shielding structure 15a. In other words, the outermost end 15e of the shielding structure 15a in the direction perpendicular to the axis Ax is located farther outward than the outermost end of the through hole 26 in the direction perpendicular to the axis Ax. With this configuration, even if water flows toward the through hole 26, the water flow is less likely to directly strike the attachment member 10.

A distance D1 between the outermost end 15e of the shielding structure 15a in the direction perpendicular to the axis Ax and the outermost end of the through hole 26 is not limited to a specific value. The distance D1 is, for example, (d1−d2)/2 or more. d1 is an outer diameter of a contact portion 10p of the attachment member 10, at which the attachment member 10 is in contact with the outer surface of the housing 2. d2 is an outer diameter of the through hole 26 in the direction perpendicular to the axis Ax. The distance D1 is, for example, 1.0 mm or more. In this case, even if water flows toward the through hole 26, the water flow is less likely to strike directly the attachment member 10. The distance D1 is, for example, 3.5 mm or less.

The shortest distance between the outermost end 15e of the shielding structure 15a and an inner surface of the covering member 20 is not limited to a specific value. The shortest distance is, for example, 0.5 mm or more.

The shielding structure 15a, for example, has a sloped surface 15s. The sloped surface 15s is formed directly below the through hole 26 and extends away from the flat portion 21 outward in a direction perpendicular to the axis Ax. With this configuration, even if water flows toward the through hole 26, the water flow is deflected by the shielding structure 15a outward in the direction perpendicular to the axis Ax, and the water is easily drained to the exterior of the covering member 20.

As shown in FIG. 4, a tip 22p of the side portion 22 is disposed between a plane P1_{0.4} and a plane P2, for example. The attachment member 10 has a contact portion 10p to be in contact with the outer surface of the housing 2 when the component 1a is attached to the housing 2. The plane P1_{0.4} and the plane P2 are each a plane parallel to the flat portion 21. The plane P1_{0.4} is a plane 0.4 mm away from the contact portion 10p toward the flat portion 21 in the thickness direction of the flat portion 21. The plane P2 is a plane 0.3 mm away from the contact portion 10p in a direction opposite to the flat portion 21 in the thickness direction of the flat portion 21. With this configuration, when the component 1a is attached to the housing 2, a gap is less likely to be formed between the outer surface of the housing 2 and the tip 22p. Or the gap between the outer surface of the housing 2 and the tip 22p is likely to be smaller. Therefore, even if water flows in the exterior of the covering member 20 toward the tip 22p of the side portion 22, the water flow is less likely to directly strike the attachment member 10. The tip 22p of the side portion 22 may be disposed between a plane P1_{0.3} and the plane P2, may be disposed between a plane P1_{0.2} and the plane P2, or may be disposed between a plane P1_{0.1} and the plane P2. The plane P1_{0.3} is a plane 0.3 mm away from the contact portion 10p toward the flat portion 21 in the thickness direction of the flat portion 21. The plane P1_{0.2} is a plane 0.2 mm away from the contact portion 10p toward the flat portion 21 in the thickness direction of the flat portion 21. The plane P1_{0.1} is a plane 0.1 mm away from the contact portion 10p toward the flat portion 21 in the thickness direction of the flat portion 21.

The attachment member 10 is not limited to a specific member. The attachment member 10 may be, for example, a valve. In this case, it is possible to control discharge of a gas to the exterior of the housing 2 and supply of a gas to the interior of the housing 2 by, for example, attaching the component 1a to the housing 2.

In the case where the attachment member 10 is a valve, the valve is not limited to a specific valve. As shown in FIG. 2, the valve as the attachment member 10 is, for example, an umbrella valve. As shown in FIG. 3A, the attachment member 10 as the umbrella valve includes, for example, a shaft portion 10a and a valve body 10b. The shaft portion 10a is a tubular portion. When the component 1a is attached to the housing 2, the shaft portion 10a is in an airtight contact with the housing 2 at the opening 2a. On the outer surface of the shaft portion 10a at a position away from one end of the shaft portion 10a in a direction parallel to axis Ax, an annular protruding portion 10d is formed. When the component 1a is attached to the housing 2, the protruding portion 10d is in contact with a part of the housing 2 adjacent to the opening 2a in the interior 2i of the housing 2. This makes it easy to prevent the component 1a attached to the housing 2 from unintentionally detached from the housing 2. In the interior of the shaft portion 10a, one end of a ventilation path 11 for communication between the interior 2i of the housing 2 and the exterior 2e of the housing 2 is formed.

As shown in FIG. 3A, the valve member 10b extends, for example, from the shaft portion 10a. The valve member 10b is, for example, an annular portion extending from the other end of the shaft portion 10a in a direction parallel to the axis Ax and inclined with respect to the axis Ax with respect to a plane perpendicular to the axis Ax. When the component 1a is attached to the housing 2, the valve member 10b has an outer peripheral portion 10q being in airtight contact with the outer surface of the housing 2 and forming an annular sealed portion 10s. As shown in FIG. 2 and FIG. 3A, the housing 2 has a ventilation hole 2b around the opening 2a of the housing 2. Thereby, the internal pressure of the housing 2 acts on the inside of the valve body 10b. In the case where the pressure in the interior of the housing 2 suddenly increases and the pressure difference between the interior and the exterior of the housing 2 exceeds a predetermined value for any reasons, the valve body 10b deforms to bend back, and the outer peripheral portion 10q of the valve body 10b, which forms the annular sealed portion 10s, separates from the outer surface of the housing 2. As a result, the pressure difference between the interior and exterior of the housing 2 decreases, and the outer peripheral portion 10q of the valve body 10b again forms the annular sealed portion 10s.

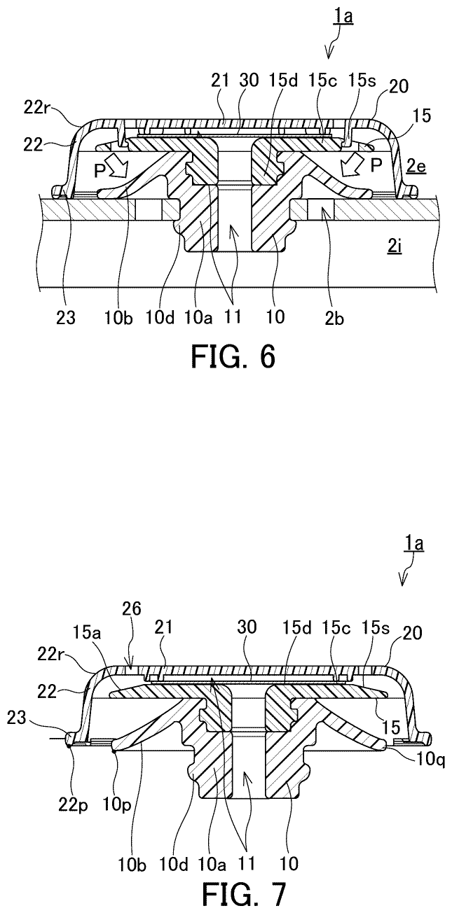

As shown in FIG. 4, for example, the valve member 10b extends straight between the outer peripheral portion 10q and the boundary between the valve member 10b and the shaft portion 10a. With this configuration, for example, as shown in FIG. 6, when an external pressure P, such as water pressure, acts on the umbrella valve of the component 1a being attached to the housing 2, the valve member 10b is likely to deform so that the contact area between the peripheral portion 10q and the outer surface of the housing 2 is increased. An external pressure P may be generated, for example, when an assembly including the component 1a and the housing 2 is submerged in water. Therefore, for example, since the valve body 10b extends straight toward the outer peripheral portion 10q, the waterproof properties of the assembly are easily improved. As shown in FIG. 7, the valve body 10b may extend inwardly curved between the outer peripheral portion 10q and the boundary between the valve body 10b and the shaft portion 10a. Similarly in such a case, when an external pressure P, such as water pressure, acts on the umbrella valve of the component 1a being attached to the housing 2, the valve member 10b is likely to deform so that the contact area between the peripheral portion 10q and the outer surface of the housing 2 is increased and the waterproof properties of the assembly are easily improved. The valve member 10b extends, for example, without outwardly curving between the outer peripheral portion 10q and the boundary between the valve member 10b and the shaft portion 10a.

As an umbrella valve, a dome-shaped umbrella valve having a dome-shaped structure with the valve body outwardly curved is known. The attachment member 10 may be such an umbrella valve. Meanwhile, in such an umbrella valve, it is difficult to increase the area for contacting with the housing in order to provide a sealed state, and as a result, when an external pressure acts on the umbrella valve due to submersion or the like, the sealed state may be released, making it difficult to maintain the waterproofness.

As shown in FIG. 3A, the component 1a further includes a gas-permeable membrane 30. The gas-permeable membrane 30 is permeable to a gas guided to an interior 2i or an exterior 2e of the housing 2 when the component 1a is attached to the housing 2. With this configuration, for example, the pressure in the interior 2i of the housing 2 can be easily controlled. In addition, foreign matters are less likely to enter the interior 2i of the housing 20.

The gas-permeable membrane 30 is disposed adjacent to the ventilation path 11. The gas-permeable membrane 30 is not limited to a particular gas-permeable membrane as long as the gas-permeable membrane 30 has desirable gas permeability. The gas-permeable membrane 30 may be a single layer membrane, or may be a multilayer membrane. In the case where the gas-permeable membrane 30 is a multilayer membrane, each layer thereof can be formed of one selected from the group consisting of a porous membrane, a nonwoven fabric, a cloth, and a mesh. The gas-permeable membrane 30 may include: a porous membrane and a nonwoven fabric; a porous membrane and at least one of a cloth and a mesh; or a plurality of nonwoven fabrics. Typically, the gas-permeable membrane 30 is composed of an organic polymer material (resin). The material of the porous membrane is, for example, a fluorine resin. As the fluorine resin can be used, for example, polytetrafluoroethylene (PTFE), polychlorotrifluoroethylene, a tetrafluoroethylene-hexafluoropropylene copolymer, or a tetrafluoroethylene-ethylene copolymer. The material of the porous membrane may be a polyolefin, such as a homopolymer or copolymer of a monomer(s) such as ethylene, propylene, or 4-methylpentene-1,1-butene. The porous membrane may be a porous nanofiber membrane made of polyacrylonitrile, nylon, polylactic acid or the like. The porous membrane can be manufactured by a known drawing or extraction technique. Examples of the materials of the nonwoven fabric, the cloth, and the mesh include polyesters such as polyethylene terephthalate, polyolefins such as polyethylene and polypropylene, nylon, aramids, and ethylene-vinyl acetate copolymer.

The gas-permeable membrane 30 desirably includes a porous PTFE membrane. The porous PTFE membrane can ensure gas permeability with a small area and can effectively prevent entry of a foreign matter. The porous PTFE membrane may be laid on a gas-permeable supporting member such as a nonwoven fabric.

The thickness of the gas-permeable membrane 30 is not limited to a particular thickness. The thickness of the gas-permeable membrane 30 is, for example, 1 μm or more and 5 mm or less. The gas permeation rate of the gas-permeable membrane 30 is 0.1 to 300 sec/100 mL, for example, when measured according to Method B (Gurley method) of gas permeability measurement specified in Japanese Industrial Standards (JIS) L 1096.

The gas-permeable membrane 30 may be subject to a liquid-repellent treatment as necessary. The liquid-repellent treatment is performed, for example, by forming a liquid-repellent coating film containing a fluorine surface modifier having a perfluoroalkyl group on the gas-permeable membrane 30. The method for forming the liquid-repellent coating film is not limited to a particular formation method. The liquid-repellent coating film is formed, for example, by coating a porous resin membrane with a solution or dispersion of a fluorine surface modifier having a perfluoroalkyl group by a method such as air spraying, electrostatic spraying, dip coating, spin coating, roll coating, curtain flow coating, or impregnation. The liquid-repellent coating film may be formed by electrodeposition or plasma polymerization.

As shown in FIG. 2 and FIG. 3A, the component 1a further includes, for example, a support member 15. The support member 15 supports the gas-permeable membrane 30. The support member 15 includes, for example, an annular and plate-like support portion 15c and a tubular shaft portion 15d. The shaft portion 15d is fitted into the shaft portion 10a of the attachment member 10. In this way, the interior of the shaft portion 15d and the interior of the shaft portion 10a are in communication with each other to form a part of the ventilation path 11.

The support member 15c extends along a plane perpendicular to the axis Ax. For example, a shielding structure 15a is formed with the peripheral portion of the support member 15c.

The gas-permeable membrane 30 is fixed to the support member 15c so as to cover the interior of the shaft portion 15d. A space serving as another part of the ventilation path 11 is formed between the gas-permeable membrane 30 and the flat portion 21 of the covering member 20. This space is in communication with the through hole 26. This allows ventilation between the interior 2i of the housing 2 and the exterior space of the covering member 20 adjacent to the through hole 26.

As shown in FIG. 3A, the covering member 20 includes a hook 27 that protrudes into the interior of the covering member 20 at the peripheral portion of the flat portion 21. The hook 27 is fixed to the support member 15c by snap-fitting. The support portion 15c has a hole 15b on its peripheral portion for engaging the hook 27. The covering member 20 may be fixed to the support member 15 by thermal caulking or the like.

As described above, in the component 1a, the attachment member 10 is a valve, and the component 1a may include a gas-permeable membrane 30. In this case, a ratio S₃₀/S_{P} is not limited to a specific value, where S₃₀ is an effective ventilation area S₃₀ of the gas-permeable membrane 30, and S_{P} is a projection area obtained by projecting a valve as an attachment member 10 on a plane parallel to an opening plane formed by the opening 2a. The ratio S₃₀/S_{P} is, for example, 0.1 or more. In this case, for example, in a normal operating environment of the assembly, the ventilation volume of the ventilation path 11 is likely to be increased, and a large load is less likely to be imposed on an outer peripheral portion 10q of a valve as the attachment member 10, where the outer peripheral portion 10q forms a sealed portion 10s that seals the outer surface of the housing 2. Therefore, the component 1a is likely to have the desired durability. The plane parallel to the opening plane formed by the opening 2a is, for example, a plane perpendicular to the axis Ax. The effective ventilation area S₃₀ corresponds, for example, to the area enclosed by a joint between the gas-permeable membrane 30 and the support member 15 in a plan view of the gas-permeable membrane 30. Note that the gap between the support member 15 and a portion enclosed by the joint in the gas-permeable membrane 30 can be included in the ventilation path 11.

The ratio S₃₀/S_{P} is preferably 0.2 or more, and more desirably 0.3 or more. The ratio S₃₀/S_{P} is, for example, 1 or less.

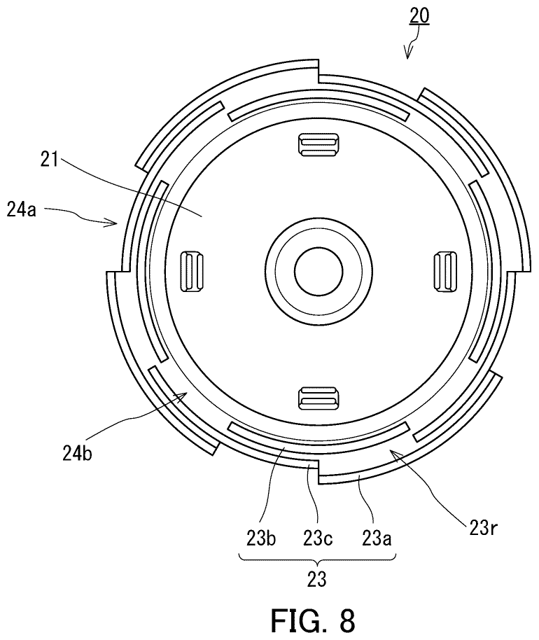

FIG. 8 is a plan view showing another example of the covering member 20. In FIG. 8, the interior of the covering member 20 is shown in a plan view. As shown in FIG. 8, the covering member 20 may include a peripheral portion 23 having a double wall structure. This double wall structure forms a communication path 23r for a communication between an interior 20i of the covering member 20 and an exterior 20e of the covering member 20. With this configuration, even if water flows in the exterior 20e of the covering member 20 toward the peripheral portion 23, the double wall structure may prevent the water flow from directly striking the attachment member 10. In addition, such a water flow is less likely to be deflected by the outer surface of the housing 2, and the covering member 20 is less likely to rise up. Even if water enters the interior 20i of the covering member 20, the water can easily be drained to the exterior of the covering member 20 through the communication path 23r.

The double wall structure at the peripheral portion 23 includes, for example, a plurality of first walls 23a, a plurality of second walls 23b, and a plurality of third walls 23c. The first walls 23a are spaced apart from one another along the outermost periphery of the peripheral portion 23 in a plan view of the covering member 20. The second walls 23b are spaced apart from one another along the innermost periphery of the peripheral portion 23 in a plan view of the covering member 20. The third walls 23c are spaced apart from one another on a circumference having a diameter smaller than the diameter of the outermost periphery of the peripheral portion 23 and larger than the diameter of the innermost periphery of the peripheral portion 23. In a part of the peripheral portion 23, the second wall 23b and the third wall 23c face each other, the part being adjacent to a space 24a between a pair of the first walls 23a adjacent to each other along the outermost periphery. In other words, in the part of the peripheral portion 23 adjacent to the space 24a between a pair of first walls 23a, the second wall 23b and third wall 23c facing each other form a double wall structure. In a part of the peripheral portion 23, the first wall 23a and the third wall 23c face each other, the part being adjacent to a space 24b between a pair of the second walls 23b adjacent to each other along the innermost periphery. In other words, in the part of the peripheral portion 23 adjacent to the space 24b between a pair of second walls 23b, the first wall 23a and the third wall 23c facing each other form a double wall structure. With this configuration, the entire periphery of the peripheral portion 23 is easily formed with a double wall structure. In addition, the communication path 23r is likely to be in communication with the interior 20i of the covering member 20 at a plurality of locations and is likely to be in communication with the exterior 20e of the covering member 20 at a plurality of locations. As a result, water is more easily drained to the exterior of the covering member 20 through the communication path 23r.

As shown in FIG. 4, the first wall 23a and the third wall 23c form the outermost part on the entire periphery of the peripheral portion 23. With this configuration, water flowing in the exterior 20e of the covering member 20 toward the peripheral portion 23 is less likely to be deflected by the outer surface of the housing 2, and the covering member 20 is less likely to rise up. For example, the space 24a between a pair of first walls 23a adjacent to each other along the outermost periphery of the peripheral portion 23 is open toward the exterior 20e of the covering member 20 in a direction parallel to the axis Ax and in a direction perpendicular to the axis Ax. With this configuration, water flowing toward the peripheral portion 23 is less likely to be deflected by the outer surface of housing 2, whereby the covering member 20 is less likely to rise up.

As shown in FIG. 1, the assembly 3 is provided by attaching the component 1a to the housing 2.

In the assembly 3, an article to be accommodated in the housing 2 is not limited to a specific article. The housing 2 may be, for example, a housing for accommodating a lithium-ion secondary battery. The housing 2 may be a housing for accommodating a battery other than the lithium-ion secondary battery, an electronic device, an electrical appliance, an electrical machine, a precision machine, or an optical device.

The component 1a may be modified from various viewpoints. For example, in the component 1a, the attachment member 10 may be configured to be joined to the housing 2. The attachment member 10 may be, for example, joined to the housing 2 by use of a given adhesive agent, or may be joined to the housing 2 by ultrasonic welding or heat sealing.

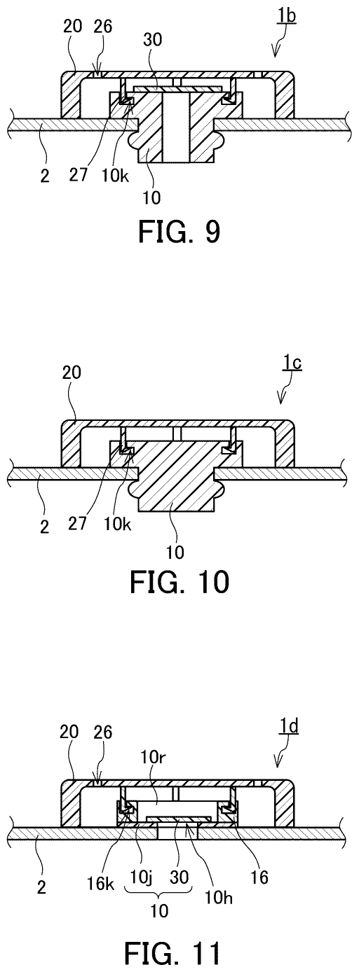

The component 1a may be modified, for example, to a component 1b shown in FIG. 9, a component 1c shown in FIG. 10, or a component 1d shown in FIG. 11. Each of the components 1b, 1c, and 1d is configured similarly to the component 1a, except for some elements described. Elements of the components 1b, 1c, and 1d, which are the same as or correspond to the elements of the component 1a, are given the same reference numerals, and detailed description thereof will be omitted. The description of the component 1a applies to the components 1b, 1c, and 1d unless technically contradictory.

As shown in FIG. 9, in the component 1b, the attachment member 10 is configured as a member for supporting the gas-permeable membrane 30. The attachment member 10 can be fixed to the housing 2 by press-fitting. The attachment member 10 has a recess 10k. In the state where the hook 27 of the covering member 20 is inserted into the recess 10k, the hook 27 is snap-fit to the attachment member 10. In this way, in the component 1b, the covering member 20 is directly attached to the attachment member 10. The attachment member 10 is a tubular member, and its interior forms a part of the ventilation path 11.

As shown in FIG. 10, in the component 1c, the attachment member 10 is a plug. The attachment member 10 can be fixed to the housing 2 by press-fitting. In the component 1c, similarly to the component 1b, the covering member 20 is directly attached to the attachment member 10.

As shown in FIG. 11, in the component 1d, the attachment member 10 includes a gas-permeable membrane 30 and a pressure-sensitive adhesive sheet 10j. The pressure-sensitive adhesive sheet 10j is, for example, shaped annular in a plan view and has at its center a hole 10h corresponding to the opening 2a of the housing 2. The gas-permeable membrane 30 is fixed to one principal surface of the pressure-sensitive adhesive sheet 10j so as to cover the hole 10h. With the hole 10h and the opening 2a positioned, the other principal surface of the pressure-sensitive adhesive sheet 10j is pressed against a part of the outer surface of the housing 2, the part being adjacent to the opening 2a, whereby the attachment member 10 is fixed to the housing 2.

The component 1d includes a connecting member 16. The connecting member 16 is an annular member disposed around the gas-permeable membrane 30 and fixed to one principal surface of the pressure-sensitive adhesive sheet 10j. The connecting member 16 has a recess 16k. In the state where the hook 27 of the covering member 20 is inserted into the recess 16k, the hook 27 is snap-fit to the connecting member 16.

A first aspect of the present invention provides a component configured to be attached to a housing so as to cover an opening of the housing, the component including:
an attachment member to be independently fixed to the housing or joined to the housing so as to cover the opening, and
a covering member covering the attachment member.

A second aspect of the present invention provides the component according to the first aspect, wherein
the covering member includes a peripheral portion having an outer wall and an inner wall,
the outer wall has a first opening formed between an interior of the covering member and an exterior of the covering member, and
the inner wall covers the first opening along the outer wall within the interior of the covering member.

A third aspect of the present invention provides the component according to the first aspect, wherein
the covering member includes a peripheral portion having a double wall structure, and
the double wall structure forms a communication path to allow communication between an interior of the covering member and an exterior of the covering member.

A fourth aspect of the present invention provides the component according to the third aspect, wherein
the double wall structure includes a plurality of first walls, a plurality of second walls, and a plurality of third walls,
the first walls are spaced apart from one another along an outermost periphery of the peripheral portion in a plan view of the covering member,
the second walls are spaced apart from one another along an innermost periphery of the peripheral portion in a plan view of the covering member,
the third walls are spaced apart from one another on a circumference having a diameter smaller than a diameter of the outermost periphery and larger than a diameter of the innermost periphery in a plan view of the covering member,
in a part of the peripheral portion, the second wall and the third wall face each other, the part being adjacent to a space between a pair of the first walls adjacent to each other along the outermost periphery, and
in a part of the peripheral portion, the first wall and the third wall face each other, the part being adjacent to a space between a pair of the second walls adjacent to each other along the innermost periphery.

A fifth aspect of the present invention provides the component according to any one of the first to the fourth aspects, wherein
the component further includes a shielding structure,
the covering member includes a flat portion forming a central portion of the covering member,
the flat portion has a through hole, and
the shielding structure is disposed, in a thickness direction of the flat portion, between the through hole and the attachment member.

A sixth aspect of the present invention provides the component according to any one of the first to the fifth aspects, wherein
the covering member includes: a flat portion forming a central portion of the covering member; and a side portion protruding from the flat portion and forming a peripheral edge of the covering member, and
the side portion has a curved portion adjoining the flat portion.

A seventh aspect of the present invention provides the component according to the second aspect, further including a shielding structure, wherein
the covering member includes a flat portion forming a central portion of the covering member and a side portion protruding from the flat portion and forming a peripheral edge of the covering member,
the flat portion has a through hole,
the shielding structure is disposed, in the thickness direction of the flat portion, between the through hole and the attachment member, and
the side portion has a curved portion adjoining the flat portion.

An eighth aspect of the present invention provides the component according to any one of the first to the seventh aspects, wherein
the attachment member has a contact portion configured to be in contact with an outer surface of the housing when the component is attached to the housing,
the covering member includes a flat portion forming a central portion of the covering member and a side portion protruding from the flat portion and forming a peripheral edge of the covering member,
a tip of the side portion is disposed between a first plane and a second plane,
the first plane is a plane parallel to the flat portion, 0.4 mm away from the contact portion toward the flat portion in the thickness direction of the flat portion, and
the second plane is a plane parallel to the flat portion, 0.3 mm away from the contact portion in a direction opposite to the flat portion in the thickness direction of the flat portion.

A ninth aspect of the present invention provides the component according to any one of the first to the eighth aspects, wherein
the attachment member is a valve.

A tenth aspect of the present invention provides the component according to the ninth aspect, wherein
the valve is an umbrella valve.

An eleventh aspect of the present invention provides the component according to the tenth aspect, wherein
the umbrella valve includes: a shaft portion configured to be in airtight contact with the housing at the opening of the housing when the component is attached to the housing; and a valve body extending from the shaft portion and having an outer peripheral portion that forms an annular sealing portion at an interface between the valve body and an outer surface of the housing when the component is attached to the housing, and
the valve body extends straight or inwardly curved between the outer peripheral portion and a boundary between the valve body and the shaft portion.

A twelfth aspect of the present invention provides the component according to any one of the first to the eleventh aspects, further including a gas-permeable membrane that is permeable to a gas guided to an interior or an exterior of the housing when the component is attached to the housing.

A thirteenth aspect of the present invention provides the component according to any one of the first to the eleventh aspects, further including a gas-permeable membrane that is permeable to a gas guided to an interior or exterior of the housing when the component is attached to the housing, wherein
when the valve is projected on a plane parallel to an opening plane formed by the opening, a ratio of an effective ventilation area of the gas-permeable membrane to a projected area of the valve is 0.1 or more.

A fourteenth aspect of the present invention provides the component according to any one of the first to the thirteenth aspects, wherein
the housing is a housing for accommodating a lithium-ion secondary battery.

A fifteenth aspect of the present invention provides an assembly including:
a housing having an opening; and
a component attached to the housing so as to cover the opening of the housing, wherein
the component includes:
an attachment member independently fixed to the housing or joined to the housing so as to cover the opening; and
a covering member covering the attachment member.

1. A component configured to be attached to a housing so as to cover an opening of the housing, the component comprising:
an attachment member to be independently fixed to the housing or joined to the housing so as to cover the opening, and
a covering member covering the attachment member.

2. The component according to claim 1, wherein
the covering member includes a peripheral portion having an outer wall and an inner wall,
the outer wall has a first opening formed between an interior of the covering member and an exterior of the covering member, and
the inner wall covers the first opening along the outer wall within the interior of the covering member.

3. The component according to claim 1, wherein
the covering member includes a peripheral portion having a double wall structure, and
the double wall structure forms a communication path to allow communication between an interior of the covering member and an exterior of the covering member.

4. The component according to claim 3, wherein
the double wall structure includes a plurality of first walls, a plurality of second walls, and a plurality of third walls,
the first walls are spaced apart from one another along an outermost periphery of the peripheral portion in a plan view of the covering member,
the second walls are spaced apart from one another along an innermost periphery of the peripheral portion in a plan view of the covering member,
the third walls are spaced apart from one another on a circumference having a diameter smaller than a diameter of the outermost periphery and larger than a diameter of the innermost periphery in a plan view of the covering member,
in a part of the peripheral portion, the second wall and the third wall face each other, the part being adjacent to a space between a pair of the first walls adjacent to each other along the outermost periphery, and
in a part of the peripheral portion, the first wall and the third wall face each other, the part being adjacent to a space between a pair of the second walls adjacent to each other along the innermost periphery.

5. The component according to claim 1, wherein
the component further comprises a shielding structure,
the covering member includes a flat portion forming a central portion of the covering member,
the flat portion has a through hole, and
the shielding structure is disposed, in a thickness direction of the flat portion, between the through hole and the attachment member.

6. The component according to claim 1, wherein
the covering member includes: a flat portion forming a central portion of the covering member; and a side portion protruding from the flat portion and forming a peripheral edge of the covering member, and
the side portion has a curved portion adjoining the flat portion.

7. The component according to claim 2, further comprising a shielding structure, wherein
the covering member includes a flat portion forming a central portion of the covering member and a side portion protruding from the flat portion and forming a peripheral edge of the covering member,
the flat portion has a through hole,
the shielding structure is disposed, in the thickness direction of the flat portion, between the through hole and the attachment member, and
the side portion has a curved portion adjoining the flat portion.

8. The component according to claim 1, wherein
the attachment member has a contact portion configured to be in contact with an outer surface of the housing when the component is attached to the housing,
the covering member includes a flat portion forming a central portion of the covering member and a side portion protruding from the flat portion and forming a peripheral edge of the covering member,
a tip of the side portion is disposed between a first plane and a second plane,
the first plane is a plane parallel to the flat portion, 0.4 mm away from the contact portion toward the flat portion in the thickness direction of the flat portion, and
the second plane is a plane parallel to the flat portion, 0.3 mm away from the contact portion in a direction opposite to the flat portion in the thickness direction of the flat portion.

9. The component according to claim 1, wherein
the attachment member is a valve.

10. The component according to claim 9, wherein
the valve is an umbrella valve.

11. The component according to claim 10, wherein
the umbrella valve includes: a shaft portion configured to be in airtight contact with the housing at the opening of the housing when the component is attached to the housing; and a valve body extending from the shaft portion and having an outer peripheral portion that forms an annular sealing portion at an interface between the valve body and an outer surface of the housing when the component is attached to the housing, and
the valve body extends straight or inwardly curved between the outer peripheral portion and a boundary between the valve body and the shaft portion.

12. The component according to claim 1, further comprising a gas-permeable membrane that is permeable to a gas guided to an interior or an exterior of the housing when the component is attached to the housing.

13. The component according to claim 9, further comprising a gas-permeable membrane that is permeable to a gas guided to an interior or exterior of the housing when the component is attached to the housing, wherein
when the valve is projected on a plane parallel to an opening plane formed by the opening, a ratio of an effective ventilation area of the gas-permeable membrane to a projected area of the valve is 0.1 or more.

14. The component according to claim 1, wherein
the housing is a housing for accommodating a lithium-ion secondary battery.

15. An assembly comprising:
a housing having an opening; and
a component attached to the housing so as to cover the opening of the housing, wherein
the component comprises:
an attachment member independently fixed to the housing or joined to the housing so as to cover the opening; and
a covering member covering the attachment member.
